(19) United States
(12) Patent Application Publication
(10) Pub. No.: US 2025/0006699 A1
(43) Pub. Date: Jan. 2, 2025

(54) ORTHOGONAL BRIDGE PACKAGING TECHNOLOGY

(71) Applicant: International Business Machines Corporation, Armonk, NY (US)

(72) Inventors: John Knickerbocker, Monroe, NY (US); Mukta Ghate Farooq, Hopewell Junction, NY (US); Keiji Matsumoto, Yokohama-shi (JP)

(21) Appl. No.: 18/216,749

(22) Filed: Jun. 30, 2023

(51) Int. Cl. H01L 25/065; H01L 23/00; H01L 23/538; H01L 25/00

(52) U.S. Cl. CPC H01L 25/0657; H01L 23/5385; H01L 24/16; H01L 24/17; H01L 25/0652; H01L 25/50; H01L 23/3731; H01L 23/3732; H01L 23/3736; H01L 23/3738; H01L 2224/16145; H01L 2224/16155; H01L 2224/16225; H01L 2224/17181; H01L 2224/17183; H01L 2225/06513; H01L 2225/06517; H01L 2225/06589

(57) ABSTRACT

A package structure includes a substrate having an upper surface; a first chip package positioned on the upper surface of the substrate, the first chip package comprising a first chip having a first integrated circuit connected to a first redistribution layer; a second chip package positioned on the upper surface of the substrate, the second chip package comprising a second chip having a second integrated circuit connected to a second redistribution layer; an orthogonal bridge positioned between the first chip package and the second chip package and having an interconnection to the first redistribution layer and the second redistribution layer; and a heat spreader positioned in direct contact with at least one of the first chip package, the second chip package, or the orthogonal bridge. The orthogonal bridge is arranged substantially orthogonal to the upper surface of the substrate.

### BACKGROUND

The exemplary embodiments described herein relate generally to semiconductor package structures and, more specifically, to semiconductor package structures employing bridge technologies to connect semiconductor chip stacks.

Heterogeneous integration (HI) with regard to semiconductor devices allows for the realization of high speed and high bandwidth communication between chips (for example, CPU, GPU, and memory). The modular nature of HI allows for the use of packaging technologies to combine discrete chips, which may be of various sizes.

Silicon bridge technology may be used with HI to connect various kinds of chips. For example, one type of silicon horizontal bridge technology is embedded multi-die interconnect bridging (EMIB), which provides an alternative solution to a silicon interposer and uses silicon only in areas where two dies are connected. Another type of silicon horizontal bridge technology is directed bonded heterogenous integration (DBHi), which involves the use of a silicon bridge directly bonded to and in between processor chips using copper pillars, thus allowing high-bandwidth low-latency low-power communication between the chips. Horizontal bridge technology may also be used in fan-out wafer-level packaging (FOWLP). Still other horizontal bridge technology for high-performance computing (HPC) applications may include 4-dimensional integration (4Di) bridging, which involves surface wiring to edges of memory chips and the joining of “cube memory chips” to packages.

However, current silicon bridge technology lacks the capabilities to enable various kinds of HI architectures, including chip stacks. It is also incapable of eliminating through-silicon vias (TSVs) in chip stacks since a bridge operates to deliver power, ground, and signal to chips stacks, and the use of TSVs detracts from such operation. Also, thermal management of the overall chip structure is less efficient in current silicon bridge technology.

### BRIEF SUMMARY

In one exemplary aspect, a package structure comprises: a substrate having an upper surface; a first chip package positioned on the upper surface of the substrate, the first chip package comprising a first chip having a first integrated circuit connected to a first redistribution layer; a second chip package positioned on the upper surface of the substrate, the second chip package comprising a second chip having a second integrated circuit connected to a second redistribution layer; an orthogonal bridge positioned between the first chip package and the second chip package and having an interconnection to the first redistribution layer and the second redistribution layer; and a heat spreader positioned in direct contact with at least one of the first chip package, the second chip package, or the orthogonal bridge. The orthogonal bridge is arranged substantially orthogonal to the upper surface of the substrate.

The heat spreader may comprise at least one of aluminum, copper, or diamond. The first chip package and the second chip package may lack through-silicon vias. The interconnections of the orthogonal bridge to the first redistribution layer and the second redistribution layer may be solder interconnections. A plurality of first chips in the first chip package may be connected to each other via at least one of hybrid bonding, fusion bonding, or thermal compression bonding. A plurality of second chips in the second chip package may be connected to each other via at least one of hybrid bonding, fusion bonding, or thermal compression bonding. The plurality of first chips in the first chip package may be separated by first bumps. The plurality of second chips in the second chip package may be separated by second bumps. The orthogonal bridge may comprise one or more of silicon, silicon carbide, silicon dioxide, diamond, a silicon nitride, a glass, a dielectric material, a solder material, polymer, copper, tantalum, tantalum nitride, nickel, gold, aluminum nitride, indium, or combinations thereof.

In another exemplary aspect, a package structure comprises: a first chip stack comprising one or more first chips; a first bridge interconnected to a first lateral edge of the first chip stack; and a heat spreader positioned in direct contact with at least one of the first chip stack or the bridge. The first chip stack and a lower edge of the bridge are positioned on a planar surface of a substrate such that the first bridge extends orthogonal to the planar surface of the substrate.

The package structure may further comprise a second bridge having a lower edge positioned on the planar surface of the substrate, and the second bridge interconnected to a second lateral edge of the first chip stack. The package structure may further comprise a second chip interconnected to an upper edge of the first bridge and to an upper edge of the second bridge. The first bridge and the second bridge may be cube memory chips. The heat spreader may comprise at least one of aluminum, copper, or diamond. An interconnection of the first chip stack to the first bridge may be a solder interconnection. The first bridge may transport at least one of current or voltage to the first chip stack.

In another exemplary aspect, a method comprises: assembling a plurality of chips into a stack without through-silicon vias, each chip of the plurality of chips having a redistribution layer; bonding the plurality of stacked chips together; bonding the bonding and stacked chips to a bridge at lateral edges of the chips to interconnect the redistribution layers to the bridge; bonding the bonded and stacked chips and the bridge to a substrate; and attaching a heat spreader to the bonded and stacked chips. The bridge extends orthogonal to a planar surface of the substrate.

The plurality of chips may be assembled into a stack without through-silicon vias. The bonding of the plurality of stacked chips may be by at least one or hybrid bonding, fusion bonding, or thermal compression bonding. The method may further comprise underfilling space between the stacked chips.

### BRIEF DESCRIPTION OF THE SEVERAL VIEWS OF THE DRAWINGS

The foregoing and other aspects of exemplary embodiments are made more evident in the following Detailed Description, when read in conjunction with the attached Drawing Figures, wherein:

FIG. 1 is a cross sectional view of one example embodiment of a semiconductor structure employing an orthogonal bridge between chip stacks;

FIG. 2 is a top view of the semiconductor structure of FIG. 1;

FIG. 3 is a cross sectional view of another example embodiment of a semiconductor package structure having a chip stack connected to two orthogonal bridges;

FIG. 4 is a cross sectional view of another example embodiment of a semiconductor package structure using cube memory chips as orthogonal bridges;

FIG. 5 is a cross sectional view of one example of an application of a semiconductor package structure using orthogonal and horizontal bridges;

FIG. 6 is a cross sectional view of one example of an application of a semiconductor package structure using cube memory chips as orthogonal bridges coupled to chips using horizontal bridges; and

FIG. 7 is a flow process diagram showing one example of a method of manufacturing a semiconductor package structure having an orthogonal bridge.

### DETAILED DESCRIPTION

The word “exemplary” is used herein to mean “serving as an example, instance, or illustration.” Any embodiment described herein as “exemplary” is not necessarily to be construed as preferred or advantageous over other embodiments. All of the embodiments described in this Detailed Description are exemplary embodiments provided to enable persons skilled in the art to make or use the invention and not to limit the scope of the invention which is defined by the claims.

The exemplary embodiments described herein are directed to semiconductor packages in which bridges connect adjacently-positioned chip stacks, the bridges being positioned orthogonal to substrates on which the chip stacks are mounted. The chip stacks may comprise one or more chips or chiplets, each having one or more integrated circuits, and each integrated circuit having a redistribution structure.

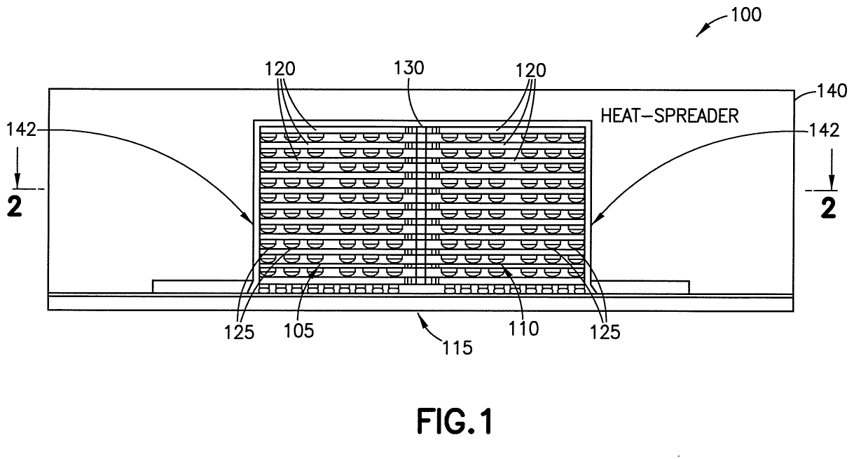

In FIG. 1, one example of a semiconductor package structure having an orthogonal bridge connecting chip stacks is shown generally at 100 and is hereinafter referred to as “structure 100.” The structure 100 comprises a first chip stack 105 and a second chip stack 110 on a substrate 115. Each chip stack 105, 110 is a package that includes a plurality of individual chiplets or chips 120, each individual chip 120 including balls or bumps 125 and being stacked and interconnected to each other by hybrid bonding, fusion bonding, or thermal compression bonding without the use of TSVs to form the chip stacks 110, 115. The use of such types of bonding minimizes coefficient of thermal expansion (CTE) mismatch and/or warpage in the chip stack. A redistribution line (RDL) is fabricated to one line of each chip 120 to connect to an integrated circuit. Spaces between each chip 120 may be underfilled or otherwise filled with an adhesive or an electrically-insulating thermal interface material (TIM). The chip stacks 115, 120 are located on the substrate 115 and connected to a redistribution layer on a planarized top surface of the substrate 115.

The orthogonal bridge 130 is located between or adjacent to the chip stacks 105, 110. Interconnections are fabricated at the lateral surfaces of each of the chip stacks 105, 110 with edges of the chips 120 in the chip stacks 105, 110 being bonded to the orthogonal bridge 130. The interconnections between the chip stacks 105, 110 and the orthogonal bridge 130 may be solder interconnections. The orthogonal bridge 130 is substantially perpendicular to the top surface of the substrate 115. In other example embodiments, one or more of the chip stacks 105, 110 may be bonded to another chip stack or to a silicon IP core.

In any embodiment, materials from which the orthogonal bridge 130 may be fabricated include, but are not limited to, silicon, silicon carbide, silicon dioxide, diamond, a silicon nitride, a glass, a dielectric material, a solder material, polymer, copper, tantalum, tantalum nitride, nickel, gold, aluminum nitride, indium, or combinations thereof.

In addition, the orthogonal bridge 130 may comprise a waveguide, a superconductor, a transistor, or a laser. The orthogonal bridge 130 may include a circuit separate from those on any of the connected chips 120. In addition to interconnections to the chip stacks 105, 110, interconnections may be made to a photonic integrated circuit (PIC) chip. Still further, the orthogonal bridge 130 may include a test channel for monitoring a known good die, thermal removal verification conditions, optical link verifications, optical link insertion loss, signal integrity, chip performance, chip functional performance metrics (for example, speed sort), voltage conditions (droop), chip functional signal integrity speed validation (PHY characterization for on module and/or off module interconnection), and clocking verification.

Still further, the orthogonal bridge 130 may be integrated into modules with a substrate 115 with organic packages, silicon packages, glass packages, ceramic packages, wafer-level or panel-level integration structures compatible with flip chip (FC) attach, ball grid array (BGA) attach, and/or hybrid or fusion bonding structures (Cu—Cu, Cu—Cu with silicon dioxide, silicon nitride, silicon oxygen nitride, dielectrics, and/or polymer dielectrics). Alternate metal-metal interconnections and dielectrics are also within the scope of the examples described herein.

A heat spreader 140 is located over and attached to the chip stacks 105, 110 and the orthogonal bridge 130 such that direct contact is maintained between edges of the chips 120 intermediately located in the chip stacks 105, 110 and between upper planar surfaces of the top chips 120 on top of the chip stacks 105, 110 at surfaces 142. Materials from which the heat spreader 140 may be fabricated include, but are not limited to, aluminum, copper, diamond, and the like. TSVs in the stacked chips 120 are eliminated, and the thickness of each stacked chip 120 can be thicker as compared to other architectures that do not employ orthogonal bridges, thus allowing for the contact area with the heat spreader to be larger. For example, a thickness of each chip 120 may be 400 micrometers (um). The heat spreader 140 (as well as other heat spreaders described below) provides for efficient thermal management in the semiconductor structure 100.

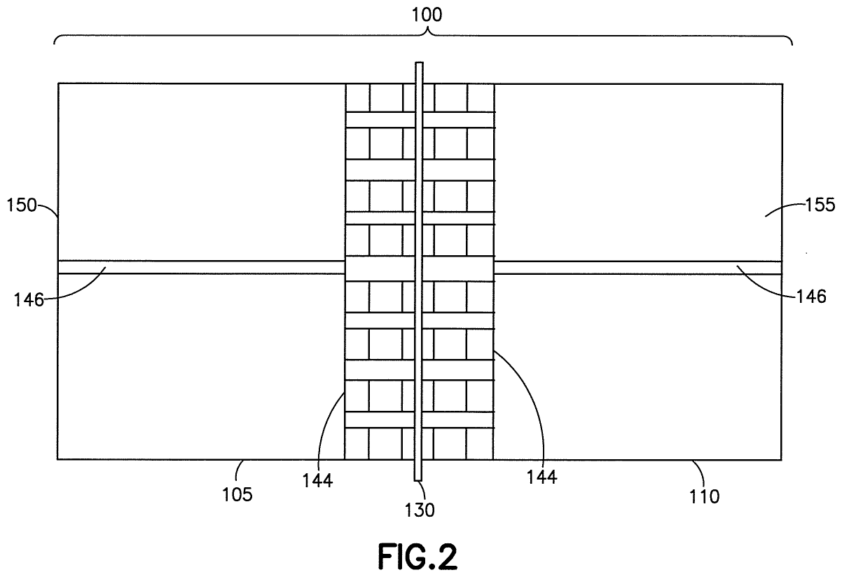

As shown in FIG. 2, the chip stacks 105, 110 are shown as being bonded to the orthogonal bridge 130 on first sides 144 and on adjacent sides 146 being bonded to additional chip stacks 150, 155 (which may or may not be bonded to the orthogonal bridge 130).

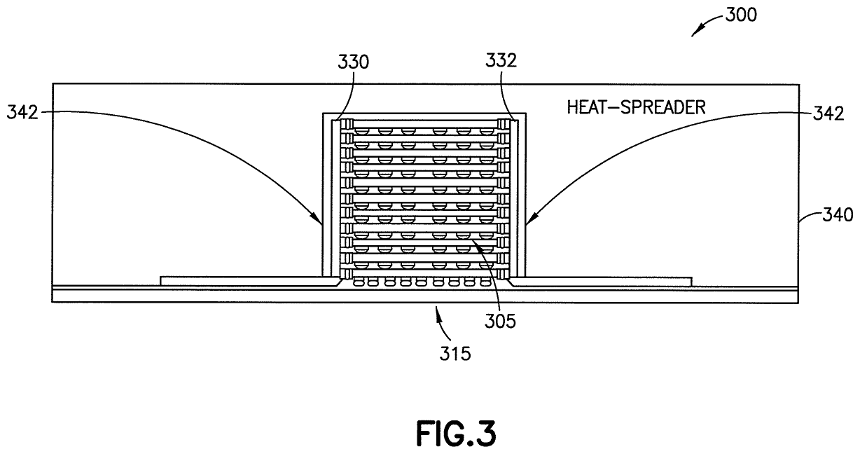

As shown in FIG. 3, another example of a semiconductor package structure connected to two orthogonal bridges is shown generally at 300. As shown, a chip stack 305 similar to the chip stacks 105, 110 indicated above is formed with an RDL and without the use of TSVs and is located on a substrate 315. The chip stack 305 is bonded to a first orthogonal bridge 330 at one side of the chip stack 305 and to a second orthogonal bridge 332 at a second side of the chip stack 305. The chip stack 305 is thus connected to the two orthogonal bridges 330, 332. As with structure 100, a heat spreader 340 is located over the chip stack 305 and the orthogonal bridges 330, 332, with direct contact being made at surfaces 342.

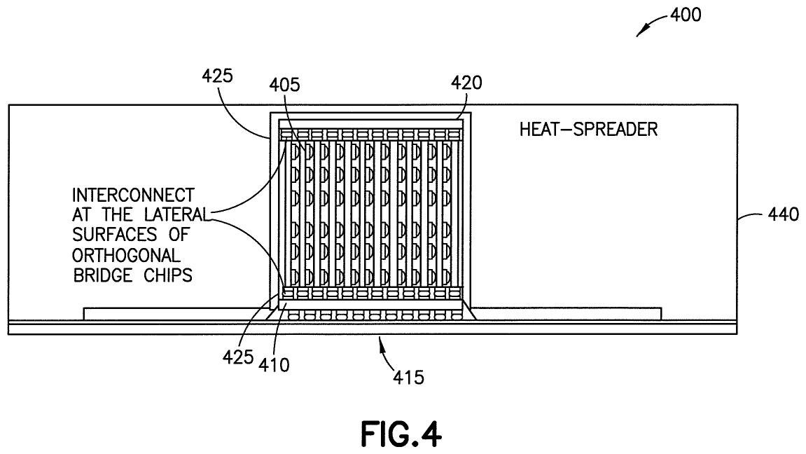

As shown in FIG. 4, another example of a semiconductor package structure is shown at 400 and is referred to as “structure 400.” In structure 400, cube memory chips 405 (and surface electrical wiring to edges of each cube memory chip 405) may be used as orthogonal bridges on a first chip 410 positioned on an upper planar surface of a substrate 415 and connecting a second chip 420 positioned on top of upper edges of the cube memory chips 405. Interconnections 425 may be located at lateral surfaces of the cube memory chips 405 forming the orthogonal bridge chips. A heat spreader 440 may be located over the first and second chips 410, 420 and the cube memory chips 405.

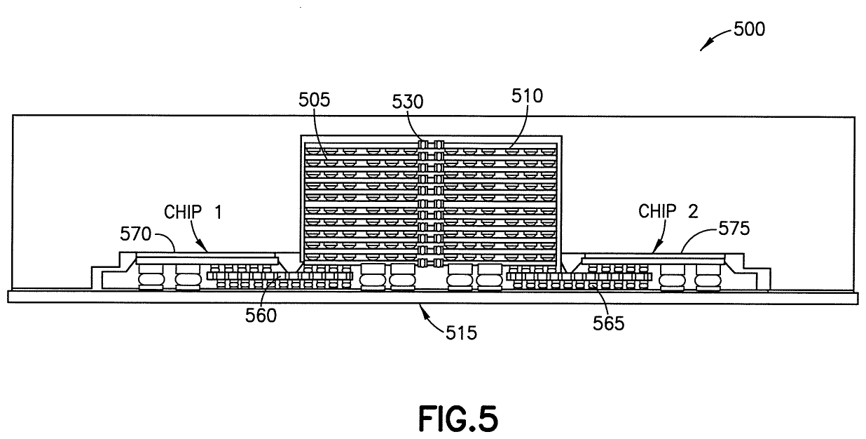

As shown in FIG. 5, one example application of the package structures as described herein is shown generally at 500 and is hereinafter referred to as “application 500.” In application 500, horizontal bridges and orthogonal bridges are combined in a unitary structure. For example, as shown, the substrate 515 may have positioned thereon the first chip stack 505 and the second chip stack 510 with the orthogonal bridge 530. However, a first horizontal bridge 560 may be positioned on the substrate 515 to couple a first chip 570 to the first chip stack 505. Additionally, a second horizontal bridge 565 may be positioned on the substrate 515 to couple a second chip 575 to the second chip stack 510. Other combinations of horizontal bridges 560, 565 with the orthogonal bridge 530 may be realized.

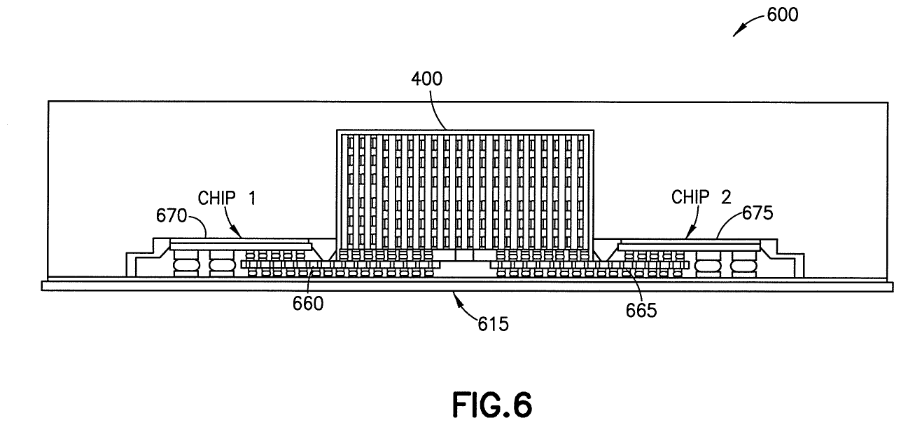

As shown in FIG. 6, another example application of the package structures as described herein is shown generally at 600 and is hereinafter referred to as “application 600.” In application 600, horizontal bridges and cube memory chips used as orthogonal bridges are combined in a unitary structure. For example, as shown, a substrate 615 may have positioned thereon the structure 400, a first portion of which is in turn coupled to a first chip 670 using a first horizontal bridge 660 and a second portion of which is in turn coupled to a second chip 675 using a second horizontal bridge 665.

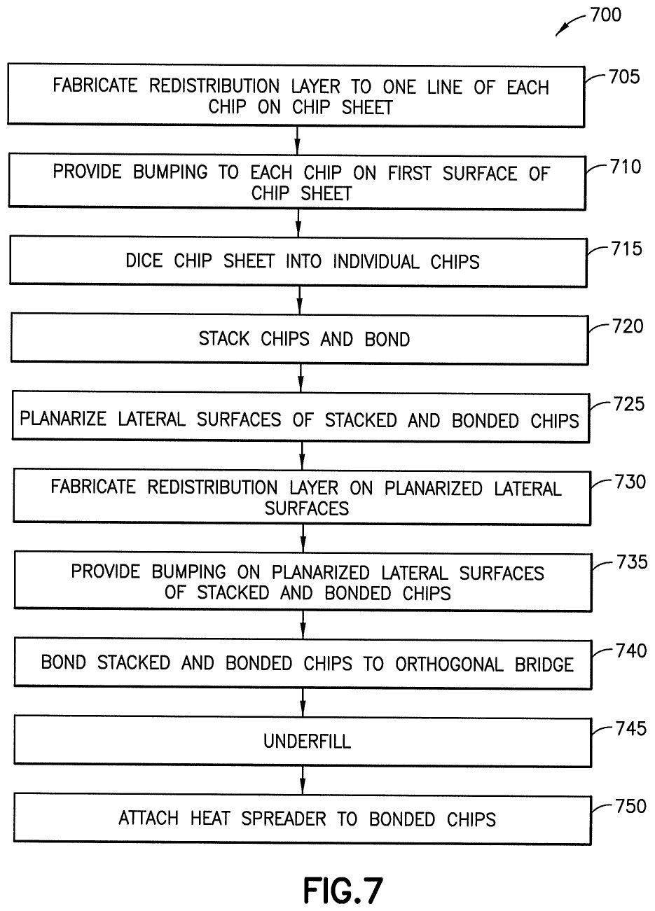

Referring now to FIG. 7, one example embodiment of a method of manufacturing a semiconductor package structure having an orthogonal bridge is shown in a flow chart indicated at 700 and referred to as “method 700.” In method 700, an RDL is fabricated to one line of each chip formed on a chip sheet, as indicated at 705. Bumping is then provided to each chip on a first surface of the chip sheet, as indicated at 710. The chip sheet is diced into individual chips, as indicated at 715. As indicated at 720, the individual chips are stacked and bonded by, for example, hybrid bonding, fusion bonding, or thermal compression bonding. As indicated at 725, lateral surfaces of the stacked and bonded chips are planarized using, for example, a chemical mechanical polish (CMP). An RDL is fabricated on the planarized lateral surface, as indicated at 730, and connected with the RDL formed at 705. Bumping is provided on the planarized lateral surfaces by, for example, electroplating or injection molded soldering (IMS), as indicated at 735. The stacked and bonded chips are bonded to an orthogonal bridge, as indicated at 740. Method 700 is not limited in this regard, however, as the stacked and bonded chips may be bonded to another chip or to a Si IP. Bonding may be carried out by rotating the orthogonal bridge, other chip, or Si IP (or the stacked and bonded chips) by ninety degrees. As indicated at 745, underfilling is performed. A heat spreader is attached, as indicated at 750.

Orthogonal bridges 130, 330, 530 (as well as cube memory chips) enable various kinds of HI architectures, including chip stacks. These bridges may be used with the architectures of modules using chiplet technologies, 2.XD technologies, as well as 3D technologies, with horizontal and vertical orientations. Because the orthogonal bridges operate to deliver power, ground, and signal to the chip stacks, the orthogonal bridges may obviate the need for TSVs in chip stacks. Furthermore, the orthogonal bridges as described herein may provide for voltage regulation, capacitance, inductance, magnetic inductance, resistance, or any computer user interface system application to multi-touch devices.

By the orthogonal bridges described in the embodiments disclosed herein, various examples of heterogenous integrations may be realized. For example, fabrication efficiencies may be improved, and lower cost opportunities may be presented in the manufacture of semiconductor architectures using orthogonal bridge technologies. Also, architecture efficiency may be improved overall in that opportunities are presented for the optional use of TSVs without a reduction in circuit area, and integrated thermal solutions may be presented for each chip. Additionally, wiring lengths may be shortened between chips.

In addition, orthogonal bridges may be formed using cube memory chips (for example, with suitable controllers and/or artificial intelligence (AI) accelerators). Combined with horizontal bridges, applications of HI become more flexible for many applications. Overall value is improved because HI may prove to be a key semiconductor packaging technology in the future.

In one aspect, a package structure comprises: a substrate having an upper surface; a first chip package positioned on the upper surface of the substrate, the first chip package comprising a first chip having a first integrated circuit connected to a first redistribution layer; a second chip package positioned on the upper surface of the substrate, the second chip package comprising a second chip having a second integrated circuit connected to a second redistribution layer; an orthogonal bridge positioned between the first chip package and the second chip package and having an interconnection to the first redistribution layer and the second redistribution layer; and a heat spreader positioned in direct contact with at least one of the first chip package, the second chip package, or the orthogonal bridge. The orthogonal bridge is arranged substantially orthogonal to the upper surface of the substrate.

The heat spreader may comprise at least one high temperature thermally conducting material such as aluminum, copper, tungsten, molybdenum, nickel, silicon, silicon carbide, silicon nitride, aluminum nitride, graphite, diamond, or combinations thereof. The first chip package and the second chip package may lack through-silicon vias. The interconnections of the orthogonal bridge to the first redistribution layer and the second redistribution layer may be solder interconnections. A plurality of first chips in the first chip package may be connected to each other via at least one of hybrid bonding, fusion bonding, or thermal compression bonding. A plurality of second chips in the second chip package may be connected to each other via at least one of hybrid bonding, fusion bonding, or thermal compression bonding. The plurality of first chips in the first chip package may be separated by first bumps. The plurality of second chips in the second chip package may be separated by second bumps. The orthogonal bridge may comprise one or more of silicon, silicon carbide, silicon dioxide, diamond, a silicon nitride, a glass, a dielectric material, a solder material, polymer, copper, tantalum, tantalum nitride, nickel, gold, aluminum nitride, indium, or combinations thereof.

In another aspect, a package structure comprises: a first chip stack comprising one or more first chips; a first bridge interconnected to a first lateral edge of the first chip stack; and a heat spreader positioned in direct contact with at least one of the first chip stack or the bridge. The first chip stack and a lower edge of the bridge are positioned on a planar surface of a substrate such that the first bridge extends orthogonal to the planar surface of the substrate.

The package structure may further comprise a second bridge having a lower edge positioned on the planar surface of the substrate, and the second bridge interconnected to a second lateral edge of the first chip stack. The package structure may further comprise a second chip interconnected to an upper edge of the first bridge and to an upper edge of the second bridge. The first bridge and the second bridge may be cube memory chips. The heat spreader may comprise at least one high temperature thermally conducting material such as aluminum, copper, tungsten, molybdenum, nickel, silicon, silicon carbide, silicon nitride, aluminum nitride, graphite, diamond, or combinations thereof. An interconnection of the first chip stack to the first bridge may be a solder interconnection. The first bridge may transport at least one of current or voltage to the first chip stack.

In another aspect, a method comprises: assembling a plurality of chips into a stack without through-silicon vias, each chip of the plurality of chips having a redistribution layer; bonding the plurality of stacked chips together; bonding the bonding and stacked chips to a bridge at lateral edges of the chips to interconnect the redistribution layers to the bridge; bonding the bonded and stacked chips and the bridge to a substrate; and attaching a heat spreader to the bonded and stacked chips. The bridge extends orthogonal to a planar surface of the substrate.

The plurality of chips may be assembled into a stack without through-silicon vias. The bonding of the plurality of stacked chips may be by at least one or hybrid bonding, fusion bonding, or thermal compression bonding. The method may further comprise underfilling space between the stacked chips.

In the foregoing description, numerous specific details are set forth, such as particular structures, components, materials, dimensions, processing steps, and techniques, in order to provide a thorough understanding of the exemplary embodiments disclosed herein. However, it will be appreciated by one of ordinary skill of the art that the exemplary embodiments disclosed herein may be practiced without these specific details. Additionally, details of well-known structures or processing steps may have been omitted or may have not been described in order to avoid obscuring the presented embodiments. It will be understood that when an element as a layer, region, or substrate is referred to as being “on” or “over” another element, it can be directly on the other element or intervening elements may also be present. In contrast, when an element is referred to as being “directly on” or “directly” over another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The description of the present invention has been presented for purposes of illustration and description, but is not intended to be exhaustive or limiting in the form disclosed. Many modifications and variations will be apparent to those of ordinary skill in the art without departing from the scope of the invention. The embodiments were chosen and described in order to best explain the principles of the invention and the practical applications, and to enable others of ordinary skill in the art to understand the invention for various embodiments with various modifications as are suited to the particular uses contemplated.

What is claimed is:

1. A package structure, comprising:
a substrate having an upper surface;
a first chip package positioned on the upper surface of the substrate, the first chip package comprising a first chip having a first integrated circuit connected to a first redistribution layer;
a second chip package positioned on the upper surface of the substrate, the second chip package comprising a second chip having a second integrated circuit connected to a second redistribution layer;
an orthogonal bridge positioned between the first chip package and the second chip package and having an interconnection to the first redistribution layer and the second redistribution layer; and
a heat spreader positioned in direct contact with at least one of the first chip package, the second chip package, or the orthogonal bridge;
wherein the orthogonal bridge is arranged substantially orthogonal to the upper surface of the substrate.

2. The package structure of claim 1, wherein the heat spreader comprises at least one of aluminum, copper, tungsten, molybdenum, nickel, silicon, silicon carbide, silicon nitride, aluminum nitride, graphite, diamond, or combinations thereof.

3. The package structure of claim 1, wherein the first chip package and the second chip package lack through-silicon vias.

4. The package structure of claim 1, wherein the interconnections of the orthogonal bridge to the first redistribution layer and the second redistribution layer are solder interconnections.

5. The package structure of claim 1, wherein a plurality of first chips in the first chip package are connected to each other via at least one of hybrid bonding, fusion bonding, or thermal compression bonding, and wherein a plurality of second chips in the second chip package are connected to each other via at least one of hybrid bonding, fusion bonding, or thermal compression bonding.

6. The package structure of claim 5, wherein the plurality of first chips in the first chip package are separated by first bumps, and wherein the plurality of second chips in the second chip package are separated by second bumps.

7. The package structure of claim 1, wherein the orthogonal bridge comprises one or more of silicon, silicon carbide, silicon dioxide, diamond, a silicon nitride, a glass, a dielectric material, a solder material, polymer, copper, tantalum, tantalum nitride, nickel, gold, aluminum nitride, indium, or combinations thereof.

8. A package structure, comprising:
a first chip stack comprising one or more first chips;
a first bridge interconnected to a first lateral edge of the first chip stack; and
a heat spreader positioned in direct contact with at least one of the first chip stack or the bridge;
wherein the first chip stack and a lower edge of the bridge are positioned on a planar surface of a substrate such that the first bridge extends orthogonal to the planar surface of the substrate.

9. The package structure of claim 8, further comprising a second bridge having a lower edge positioned on the planar surface of the substrate, and the second bridge interconnected to a second lateral edge of the first chip stack.

10. The package structure of claim 9, further comprising a second chip interconnected to an upper edge of the first bridge and to an upper edge of the second bridge.

11. The package structure of claim 10, wherein the first bridge and the second bridge are cube memory chips.

12. The package structure of claim 8, wherein the heat spreader comprises at least one of aluminum, copper, tungsten, molybdenum, nickel, silicon, silicon carbide, silicon nitride, aluminum nitride, graphite, diamond, or combinations thereof.

13. The package structure of claim 8, wherein an interconnection of the first chip stack to the first bridge is a solder interconnection.

14. The package structure of claim 8, wherein the first bridge transports at least one of current or voltage to the first chip stack.

15. A method, comprising:
assembling a plurality of chips into a stack without through-silicon vias, each chip of the plurality of chips having a redistribution layer;
bonding the plurality of stacked chips together;
bonding the bonding and stacked chips to a bridge at lateral edges of the chips to interconnect the redistribution layers to the bridge;
bonding the bonded and stacked chips and the bridge to a substrate; and
attaching a heat spreader to the bonded and stacked chips;
wherein the bridge extends orthogonal to a planar surface of the substrate.

16. The method of claim 15, wherein the plurality of chips are assembled into a stack without through-silicon vias.

17. The method of claim 15, wherein the bonding of the plurality of stacked chips is by at least one or hybrid bonding, fusion bonding, or thermal compression bonding.

18. The method of claim 15, further comprising underfilling space between the stacked chips.
